(19) United States
(12) Patent Application Publication
(10) Pub. No.: US 2006/0180569 A1
(43) Pub. Date: Aug. 17, 2006

(54) Method of manufacturing step contact window of flat display panel

(76) Inventor: Chang Hsi-Ming, Padeh City (TW)

Correspondence Address: GENUS LAW GROUP;LOWE HAUPTMAN & BERNER, LLP, 1700 DIAGONAL ROAD, SUITE 300, ALEXANDRIA, VA, 22314, US

(21) Appl. No.: 11/058,048

(22) Filed: Feb. 15, 2005

(51) Int. Cl. H01B 13/00; B44C 1/22; C23F 1/00; C30B 33/00

(52) U.S. Cl. 216/23; 216/13; 216/83; 216/58

(57) ABSTRACT

The present invention pertains to a method of manufacturing a step contact window of a flat display panel, comprising: providing a substrate, which further comprises a first electrically conductive layer, an insulating layer and a photoresist layer, forming a plurality of step structures on the photoresist layer, etching the insulating layer to form a plurality of step structures on the insulating layer, and forming a second electrically conductive layer on the first electrically conductive layer and the insulating layer. Via the aforementioned method of manufacturing a step contact window of a flat display panel of the present invention, the face structure of a plurality of step structures on the insulating layer is smoother than that of the conventional method, and thus the probability of the disconnection of the second electrically conductive will be reduced obviously even under the conditions that the thickness of the insulating layer is thicker or the insulating layer has a discontinuous interface or there is a thickness limitation of the second electrically conductive layer.

### BACKGROUND OF THE INVENTION

1. Field of the Invention

The present invention relates to a method of manufacturing a contact window, particularly to a method of manufacturing a step contact window of a flat display panel (FDP).

2. Description of the Related Art

In a conventional manufacturing process of a FDP, for the electric conduction between two electrically conductive layers below or above an insulating layer, a contact window is manufactured in order to enable both electrically conductive layers to contact with each other electrically. For example, in a Thin Film Transistor Liquid Crystal Display (TFT LCD), the method of the electric contact between a pixel electrode and the drain of a TFT is that before the formation of a pixel electrode, a contact window is formed on an insulating layer via a photolithography and an etching process in order that the portion of the drain just below the contact window can be exposed to the surroundings. After the formation of the pixel electrode above the TFT and the insulating layer, the pixel electrode and the drain can electrically contact with each other via the contact window.

As shown in FIG. 1A, a sectional view of the structure of a conventional contact window. The structure of a conventional contact window comprises a substrate 11, a first electrically conductive layer 12, an insulating layer 13 and a second electrically conductive layer 14, wherein the second electrically conductive layer 14 electrically connects the first electrically conductive layer 12 via a face structure 15 on the insulating layer 13. As shown in FIG. 1B, a flow chart of the method of manufacturing a conventional contact window. The manufacturing process of a conventional contact window comprises: providing a substrate (step 21), forming a first electrically conductive layer on the substrate (step 22), forming an insulating layer on the first electrically conductive layer (step 23), forming a photoresist layer on the insulating layer (step 24), exposing the photoresist layer in order to define an area of a contact window (step 25), removing the portion of the photoresist layer just above the area of the contact window (step 26), etching the portion of the insulating layer just below the area of the contact window (step 27) and forming a second electrically conductive layer on the insulating layer and the first electrically conductive layer (step 28).

In the manufacturing process of the conventional contact window, when the thickness of the insulating layer 13 is thicker such as beyond 10,000 Å or the insulating layer 13 has a discontinuous interface, a chamfer will be created in the etching. The chamfer will result in incomplete filling in the contact window or a disconnection of the second electrically conductive layer 14 on the face structure 15. Besides, when there is a thickness limitation of the second electrically conductive layer 14, the disconnection of the second electrically conductive layer 14 on the face structure 15 trends to happen. For example, in the OLED (Organic Light Emitting Display), the requirement of the roughness of the second electrically conductive layer 14 made of ITO (Indium Tin Oxide) or IZO (Indium zinc oxide) limits the thickness thereof, and thus the disconnection of the second electrically conductive layer 14 on the face structure 15 is apt to occur.

Whether the quality of a flat display panel is well or not often depends on whether the disconnection on the face structure 15 exists or not. Thus, it is to be an important subject to overcome the problem of the disconnection on the face structure 15, when the thickness of the insulating layer 13 is thicker, the insulating layer 13 has a discontinuous interface, or there is a thickness limitation of the second electrically conductive layer 14.

### SUMMARY OF THE INVENTION

The primary object of the present invention is to solve the disconnection problem of the second electrically conductive layer on the face structure of a contact window of the flat display manufacturing process when the thickness of the insulating layer is thicker, the insulating layer has a discontinuous interface, or there is a thickness of limitation of the second electrically conductive layer, in order to improve the quality of the flat display panel.

To achieve the aforementioned objective, the present invention discloses a method of manufacturing a step contact window of a flat display panel, including: providing a substrate, which further comprises a first electrically conductive layer, an insulating layer, and a photoresist layer, forming a plurality of step structures on the photoresist layer, etching the insulating layer to form a plurality of steps on the insulating layer, and forming a second electrically conductive layer on the first electrically conductive layer and the insulating layer. Via the aforementioned method of manufacturing the step contact window of a flat display panel of the present invention, a more smooth face structure is provided, and thus the probability of the disconnection of the second electrically conductive layer on the -face structure will be reduced.

In the method of manufacturing a step contact window of a flat display panel of the present invention, the second electrically conductive layer electrically contacts with the first electrically conductive layer via a plurality of the step structures. As the face structure of the step contact window of the present invention is smoother than that of the conventional contact window, the present invention has the advantage that the probability of the disconnection of the second electrically conductive layer on the face structure will be reduced.

To clarify the objective, characteristics and advantages of the present, a preferred embodiment of the present invention is described below in co-operation with the attached drawings.

### BRIEF DESCRIPTION OF THE DRAWINGS

FIG. 1A is a sectional view of the structure of a conventional contact window;

FIG. 1B is a flow chart of a conventional method of manufacturing a contact window;

FIG. 2 is a flow chart of the method of manufacturing a step contact window of a flat display panel according to one aspect of the present invention;

FIG. 3A is a sectional view of the structure after completion of the step of providing a substrate comprising a first electrically conductive layer, an insulating layer and a photoresist layer;

FIG. 3B is a sectional view of the structure after completion of the step of forming a plurality of step structures on the photoresist layer;

FIG. 3C is a sectional view of the structure after completion of the step of etching the insulating layer to form a plurality of steps on the insulating layer; and

FIG. 3D is a sectional view of the structure after completion of the step of forming a second electrically conductive layer on the first electrically conductive layer and the insulating layer.

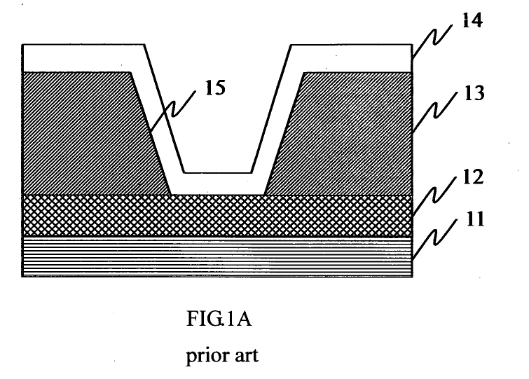

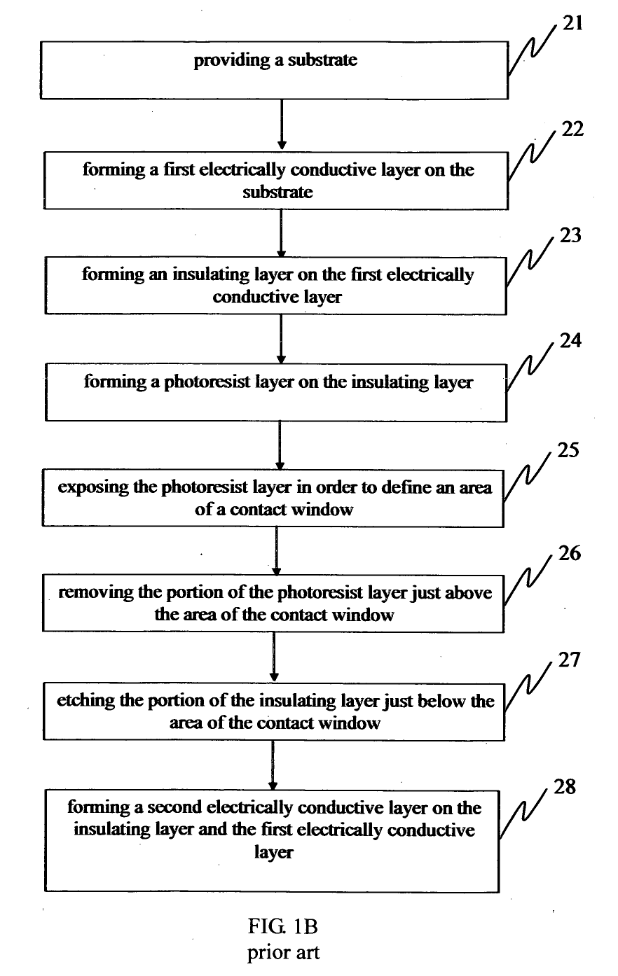

### DETAILED DESCRIPTION OF PREFERRED EMBODIMENT OF THE INVENTION

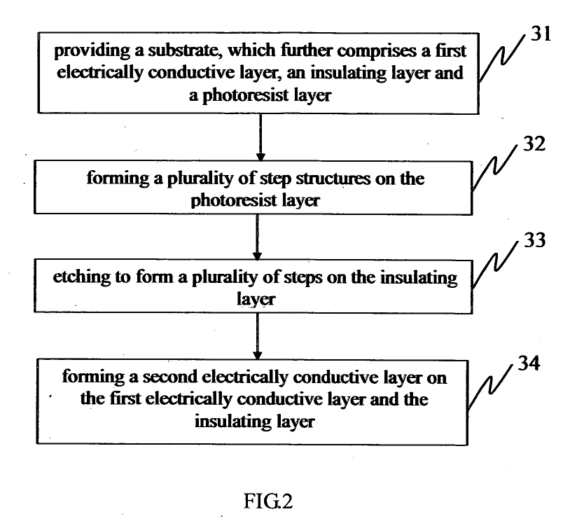

As shown in FIG. 2 a flow chart of the method of manufacturing a step contact window of a flat display panel according to one aspect of the present invention, the steps of the aforementioned method includes:

providing a substrate, which further comprises a first electrically conductive layer, an insulating layer and a photoresist layer (step 31);

forming a plurality of step structures on the photoresist layer (step 32); etching the insulating layer to form a plurality of steps on the insulating layer (step 33); and

forming a second electrically conductive layer on the first electrically conductive layer and the insulating layer (step 34).

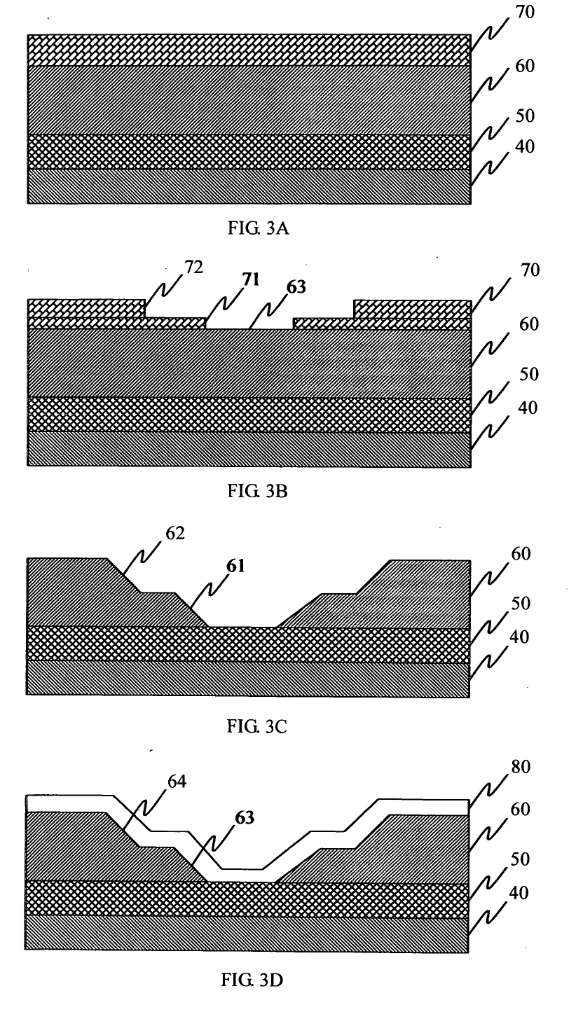

As shown in FIGS. 3A to 3D, Sectional views of the structure in the manufacturing process of the step contact window according to one embodiment of the present invention.

FIG. 3A is a sectional view of the structure after completion of step 31 providing a substrate 40, which further comprises a first electrically conductive layer 50, an insulating layer 60, and a photoresist layer 70, wherein the substrate 40 can be a glass substrate, and the first electrically conductive layer 50 can be made of an aluminum metal or an aluminum alloy, and the insulating layer 60 can be made of a silicon nitride (SiNx) or a silicon oxide (SiOx).

FIG. 3B is a sectional view of the structure after completion of step 32 forming a plurality of step structures on the photoresist layer, wherein the step 32 further comprises: photoresist coating, soft baking, exposing, post exposure baking, developing and hard baking. Wherein in the exposing procedure, a half-tone exposure process can be adopted in order that a plurality of step structures are formed on the photoresist layer 70 after developing, such as a first step 71 and a second step 72 shown in FIG. 3B.

After the aforementioned exposing and developing, an etching area 63 of the insulating layer 60 is exposed to the surroundings. The portion of the insulating layer 60 under the etching area 63 is etched for a period of time via a dry etching or a wet etching, and then an ashing procedure is utilized to remove the first step 71 of the photoresist layer in order that the portion of the insulating layer 60 under the first step 71 is exposed to the surroundings. The dry etching or the wet etching is undertaken again in order that the insulating layer 60 is etched to form step structures.

As shown in FIG. 3C, a sectional view of the structure after completion of step 33 etching the insulating layer to form a plurality of steps on the insulating layer. A plurality of step structures can be formed on the insulating layer 60 via appropriately controlling the procedure of the dry etching or the wet etching, such as a first step 61 and a second step 62 of the insulating layer 60. The aforementioned dry etching can be a reactive ion etching (RIE) or a plasma etching (PE), and the angle of the step structures can be controlled via suitable manufacturing parameters. For example, with preferred manufacturing parameters, the angle of the step structures will be ranged from 35 to 75 degrees when the silicon nitride is adopted as the insulating layer. The preferred manufacturing parameters are 10 to 15 Pa for the reaction pressure, 200 to 250 sccm for the flow rate of carbon tetrafluoride, 180 to 250 sccm for the flow rate of oxygen, 25 to 600 for the reaction temperature, and 1500 to 2000 W for the power of radio frequency.

Referring to FIG. 3D a sectional view of the structure after completion of step 34 forming a second electrically conductive layer on the first electrically conductive layer and the insulating layer. The face structure of the second electrically conductive layer 80, which can use ITO or IZO as the material, is a step structures formed onto the first step 61 and the second step 62 of the insulating layer 60. As the face structure of the step contact window of the present invention is smoother than that of the conventional contact window, the probability of the disconnection of the second electrically conductive layer on the face structure will be reduced.

According to those mentioned above, the method of manufacturing a step contact window of a flat display panel of the present invention has the advantage that the probability of the disconnection of the second electrically conductive layer on the face structure can be reduced obviously even under the conditions that the thickness of the insulating layer 60 is thicker or the insulating layer 60 has a discontinuous interface or there is a thickness limitation of the second electrically conductive layer 80. In contrast to a conventional method, the present invention has an obvious improvement.

Although the present invention has been disclosed above via the preferred embodiment, it is not intended to limit the scope of the present invention. It is to be appreciated by persons skilled in the art that any equivalent variation and modification without departing from the spirit of the present invention should be included within the scope of the present invention. The scope of the present invention is to be dependent upon the appended claims stated below.

What is claimed is:

1. A method of manufacturing a contact window of a flat display panel, comprising:
providing a substrate, which further comprises a first electrically conductive layer, an insulating layer, and a photoresist layer;
forming a plurality of step structures on said photoresist layer;
etching said insulating layer to form a plurality of step structures on said insulating layer; and
forming a second electrically conductive layer on said first electrically conductive layer and said insulating layer.

2. The method of manufacturing a contact window of a flat display panel according to claim 1, wherein said substrate includes a glass substrate.

3. The method of manufacturing a contact window of a flat display panel according to claim 1, wherein the material of said first electrically conductive layer includes an aluminum metal or an aluminum alloy.

4. The method of manufacturing a contact window of a flat display panel according to claim 1, wherein the material of said insulating layer includes silicon nitride or silicon oxide.

5. The method of manufacturing a contact window of a flat display panel according to claim 1, wherein said forming a plurality of step structures on said photoresist layer includes forming said step structures via a half tone exposure and a developing process.

6. The method of manufacturing a contact window of a flat display panel according to claim 1, wherein said etching said insulating layer to form a plurality of step structures on said insulating layer includes etching said insulating layer to form said step structures include a wet etching process.

7. The method of manufacturing a contact window of a flat display panel according to claim 1, wherein said etching said insulating layer to form a plurality of step structures on said insulating layer includes etching said insulating layer to form said step structures include a dry etching process.

8. The method of manufacturing a contact window of a flat display panel according to claim 7, wherein said dry etching includes a reactive ion etching (RIE).

9. The method of manufacturing a contact window of a flat display panel according to claim 7, wherein said dry etching includes a plasma etching (PE).

10. The method of manufacturing a contact window of a flat display panel according to claim 7, wherein the reaction pressure in said dry etching procedure ranges from 10 to 15 Pa

11. The method of manufacturing a contact window of a flat display panel according to claim 7, wherein the flow rate of carbon tetrafluoride in said dry etching procedure ranges from 200 to 250 sccm.

12. The method of manufacturing a contact window of a flat display panel according to claim 7, wherein the flow rate of oxygen in said dry-etching procedure ranges from 180 to 250 sccm.

13. The method of manufacturing a contact window of a flat display panel according to claim 7, wherein the reaction temperature of said dry etching procedure ranges from 25 to 60□.

14. The method of manufacturing a contact window of a flat display panel according to claim 7, wherein the radio frequency power in said dry-etching procedure ranges from 1500 to 2000 W.

15. The method of manufacturing a contact window of a flat display panel according to claim 1, wherein said etching said insulating layer to form a plurality of step structures on said insulating layer includes removing a step structure of said photoresist layer via an ashing procedure.

16. The method of manufacturing a contact window of a flat display panel according to claim 1, wherein the material of said second electrically conductive layer includes indium tin oxide or indium zinc oxide.
